(19) United States
(12) Patent Application Publication
(10) Pub. No.: US 2007/0087481 A1
(43) Pub. Date: Apr. 19, 2007

(54) Underfill aiding process for a tape

(75) Inventors: Shwang-Shi Bai, Hsinhua (TW); Hung-Yi Wang, Hsinhua (TW)

Correspondence Address: LOWE HAUPTMAN BERNER, LLP, 1700 DIAGONAL ROAD, SUITE 300, ALEXANDRIA, VA, 22314, US

(73) Assignee: HIMAX TECHNOLOGIES, INC., Hsinhua (TW)

(21) Appl. No.: 11/252,829

(22) Filed: Oct. 19, 2005

(51) Int. Cl. H01L 21/00

(52) U.S. Cl. 438/118

(57) ABSTRACT

A tape having a predetermined area is provided for a chip. A hole is drilled within the predetermined area. The chip is adhered to the predetermined area by underfilling an underfill material between the chip and the tape from one side of the chip. By the hole, the invention provides a short path for effectively dissipating gas to prevent voids from forming between the tape and the chip while the underfill material is applied.

### FIELD OF INVENTION

The present invention relates to an underfill aiding process for a tape. More particularly, the present invention relates to a laser drilling on a film of a chip-on-film (COF) device.

### DESCRIPTION OF RELATED ART

As semiconductor devices reach higher levels of integration, packaging technologies, such as chip bonding, have become critical. The most common technique for improving the strength of a bond is the inclusion of an underfill material between the IC chip and the package. The underfill material is typically injected or otherwise placed between the two components (e.g., an IC chip and a tape) and around the solder bumps forming the ball grid array (BGA) bonding the two components.

The underfill process requires the underfill material to flow through tiny gaps between the two components being bonded. Also, as IC chip sizes increase, the flowing of the underfill material takes more time and becomes more susceptible to void formation when the density of the BGA increases, as with more complex chips. More specifically, as the spacing between adjacent solder bumps decreases, uniform flowing of the underfill material between the two components becomes more difficult. Because voids are often the center of stress concentrations, and the residual gases inside such voids may expand when subsequently baked and cause damage, reliability of the package is all too often an issue.

### SUMMARY

It is therefore an aspect of the present invention to provide an underfill process for a tape, which drills a hole through the tape for dissipating gas and achieving void-free effect of a package.

According to one preferred embodiment of the present invention, the method provides a tape having a predetermined area for a chip. A hole is drilled within the predetermined area. The chip is adhered to the predetermined area by underfilling an underfill material between the chip and the tape from one side of the chip.

According to another preferred embodiment of the present invention, the underfill process is provided for a chip-on-film (COF) device. A film is firstly provided. A hole is drilled through the film, and the major diameter of the hole is less than 50 μm. A chip is bonded over the hole onto the film by underfilling an adhesive between the chip and the film from one side of the chip.

It is another aspect of the present invention to provide a method for packaging a chip, which makes a hole through the tape on which the chip is packaged, preventing voids and other damage caused by residual gases.

According to another preferred embodiment of the present invention, the method provides a tape. A hole is drilled through the tape, and the major diameter of the hole is less than 50 μm. Bumps of a chip are bonded over the hole onto the tape by underfilling an adhesive between the chip and the tape from one side of the chip.

It is to be understood that both the foregoing general description and the following detailed description are examples and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a flow chart of one preferred embodiment of the present invention;

FIG. 2 is a schematic view of a preferred embodiment; and

FIG. 3A and FIG. 3B are schematic views illustrating the application of an underfill material.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

The present invention drills a hole through a tape on which a chip is adhered, thus providing a short path for effectively dissipating gas to prevent voids from forming between the tape and the chip while the underfill material is applied.

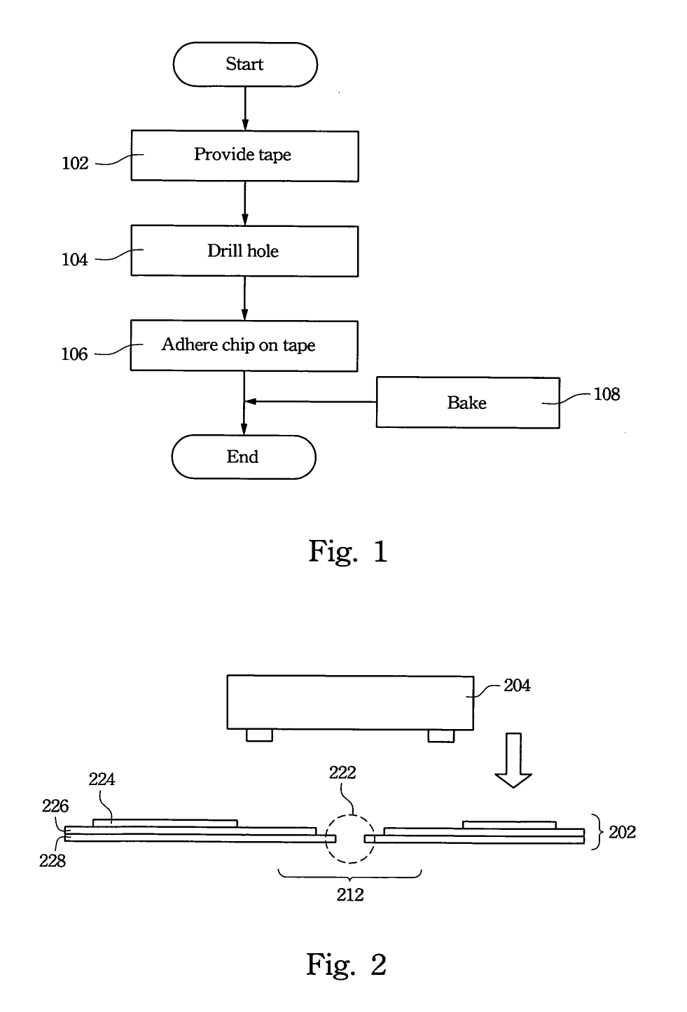

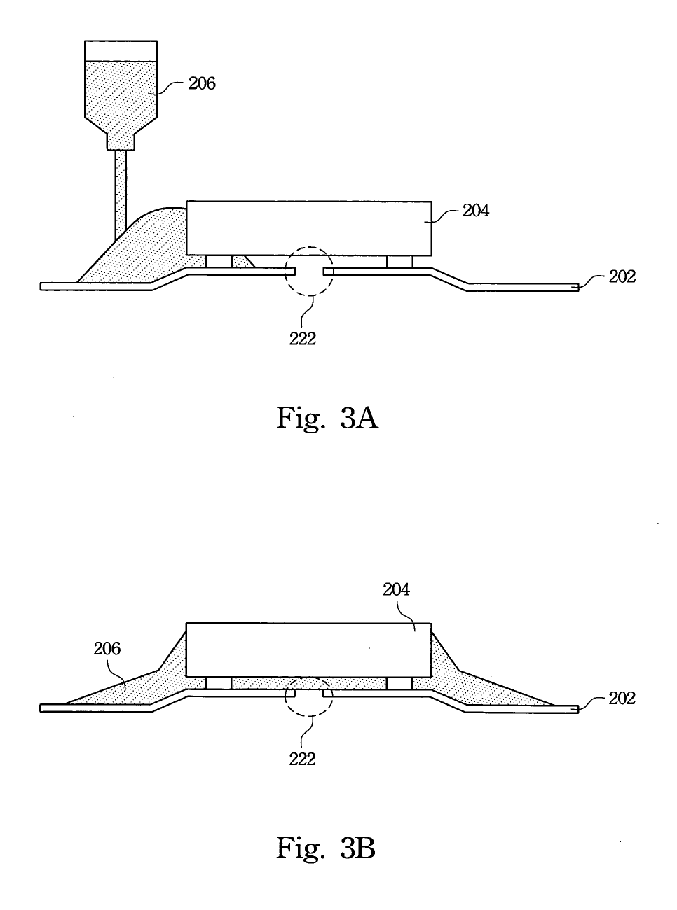

FIG. 1 is a flow chart of one preferred embodiment of the present invention, FIG. 2 is a schematic view of the preferred embodiment, and FIG. 3A and FIG. 3B are schematic views illustrating the application of an underfill material. The following description is made with reference to FIG. 1, FIG. 2, FIG. 3A and FIG. 3B. A tape 202 having a predetermined area 212 for a chip 204 is provided (step 102). A hole 222 is drilled within the predetermined area 212 (step 104). The chip 204 is adhered to the predetermined area 212 by underfilling an underfill material 206 between the chip 204 and the tape 202 from one side of the chip 204 (step 106).

More particularly, the shape of the hole 222 can be circular, elliptic, rectangular, or any other regular or irregular shape. The major diameter of the hole 222 is less than 50 μm. Preferably, the major diameter of the hole 222 is between 20 μm and 30 μm. In general, it is hard for tape manufacturers to provide tapes with holes less than 100 μm by the conventional mechanical drilling, which also may be rough and in wrong positions. Therefore, the preferred embodiment drills the hole 222 by laser drilling, which can obtain a hole of a major diameter less than 100 μm and formed in the correct position.

The hole 222 of the tape 202 may adversely affect the underfill process. For example, the underfill material 206, such as an adhesive or other suitable underfill material, may leak through the hole 222 and thus pollute the backside of the tape 202. The smaller the hole 222 is, the less the underfill material 206 leaks. The hole 222 of the preferred embodiment can prevent the underfill material 206 from leaking significantly due to its smaller diameter in addition to some special processes mentioned later.

In the preferred embodiment, the underfill process can be applied to a method for packaging a chip, where the tape 202 is a film of a chip-on-film (COF) device, and the chip 204 has several bumps for bonding the tape 202. The tape 202, the film of the COF device, has a film substrate 228 whose material is polyimide (PI), a copper film 226 disposed on the film substrate 228, and a solder resistance film 224 disposed on the copper film 226 for protecting the copper film 226 from water, chemical or other damage.

As illustrated in FIG. 2, the copper film 226 is exposed in the predetermined area 212 for bonding the bumps of the chip 204. The hole 222 within the predetermined area 212 can provide a shorter path for dissipating the residual gases than the prior art, preventing the void formation while the underfill material 206 is applied, such as by injecting or otherwise placing between the film 202 and the chip 204 from one side of the chip 204.

Furthermore, in order to avoid the mass leakage of the underfill material 206 through the hole 222, the major diameter of the hole 222 is preferably less than 50 μm and an additional baking process can be selectively applied during the underfill process. The tape 202 is baked at a predetermined temperature to solidify the underfill material 206 before it leaks out the hole 222, such as by solidifying the underfill material 206 in the hole 222 by heat. As a result, besides avoiding the mass leakage of the underfill material, the baking process can accelerate the dissipation of the residual gases and other volatile material of the underfill material 206, such as solvents.

The predetermined temperature is decided according to the underfill material 206, the size of the hole 222 and other possible process parameters, such as the flowing rate of the underfill material 206 and the heat conductivity of the film substrate 228. For example, when the underfill material 206 is epoxy resin and the size of the hole 222 is less than 50 μm, the predetermined temperature can be between 80° C. and 125° C.

In one aspect, the underfill process is provided for a chip-on-film (COF) device. A hole 222 is drilled through the film, and the major diameter of the hole 222 is less than 50 μm. A chip 204 is bonded over the hole 222 onto the film by underfilling an adhesive between the chip 204 and the film from one side of the chip 204. In another aspect, the method is provided for packaging a chip. A hole 222 is drilled through a tape 202, and the major diameter of the hole 222 is less than 50 μm. Bumps of a chip 204 are bonded over the hole 222 onto the tape 202 by underfilling an adhesive between the chip 204 and the tape 222 from one side of the chip 204.

In conclusion, the preferred embodiment dissipates residual gases, which may be caused by unbalanced flowing of the underfill material, by utilizing the hole drilled through the tape, preventing void formation or other defects. Moreover, the additional baking process can prevent mass leakage of the underfill material and accelerate the dissipation of residual gases and other volatile material of the underfill material.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An underfill process for a tape, comprising the steps of:
providing a tape having a predetermined area for a chip;
drilling a hole within the predetermined area; and
adhering the chip to the predetermined area by underfilling an underfill material between the chip and the tape from one side of the chip.

2. The underfill process for a tape as claimed in claim 1, wherein a major diameter of the hole is less than 50 μm.

3. The underfill process for a tape as claimed in claim 1, wherein a major diameter of the hole is preferably between 20 μm and 30 μm.

4. The underfill process for a tape as claimed in claim 1, wherein the hole is drilled by laser drilling.

5. The underfill process for a tape as claimed in claim 1, wherein a material of the tape is polyimide.

6. The underfill process for a tape as claimed in claim 1, further comprising:
baking the tape at a predetermined temperature to solidify the underfill material in the hole.

7. The underfill process for a tape as claimed in claim 6, wherein when a material of the underfill material is epoxy resin, the predetermined temperature is between 80° C. and 125° C.

8. An underfill process for a chip-on-film device, comprising the steps of:
providing a film;
drilling a hole through the film, wherein a major diameter of the hole is less than 50 μm; and
bonding a chip over the hole onto the film by underfilling an adhesive between the chip and the film from one side of the chip.

9. The underfill process for a chip-on-film device as claimed in claim 8, wherein the major diameter of the hole is preferably between 20 μm and 30 μm.

10. The underfill process for a chip-on-film device as claimed in claim 8, wherein the hole is drilled by laser drilling.

11. The underfill process for a chip-on-film device as claimed in claim 8, wherein a material of the film is polyimide.

12. The underfill process for a chip-on-film device as claimed in claim 8, further comprising:
baking the film at a predetermined temperature to solidify the adhesive in the hole.

13. The underfill process for a chip-on-film device as claimed in claim 12, wherein when a material of the adhesive is epoxy resin, the predetermined temperature is between 80° C. and 125° C.

14. A method for packaging a chip, comprising the steps of:
providing a tape;
drilling a hole through the tape, wherein a major diameter of the hole is less than 50 μm; and
bonding bumps of the chip over the hole onto the tape by underfilling an adhesive between the chip and the tape from one side of the chip.

15. The method for packaging a chip as claimed in claim 14, wherein the major diameter of the hole is preferably between 20 μm and 30 82 m.

16. The method for packaging a chip as claimed in claim 14, wherein the hole is drilled by laser drilling.

17. The method for packaging a chip as claimed in claim 14, wherein a material of the tape is polyimide.

18. The method for packaging a chip as claimed in claim 14, further comprising:
baking the tape at a predetermined temperature to solidify the adhesive in the hole.

19. The method for packaging a chip as claimed in claim 18, wherein when a material of the adhesive is epoxy resin, the predetermined temperature is between 80° C. and 125° C.
